(19) United States
(12) Patent Application Publication
(10) Pub. No.: US 2014/0225230 A1
(43) Pub. Date: Aug. 14, 2014

(54) SEMICONDUCTOR PACKAGE AND METHOD OF FORMING THE SAME

(71) Applicant: Samsung Electronics Co., Ltd., Suwon-si (KR)

(72) Inventor: WOOJAE KIM, Hwaseong-si (KR)

(73) Assignee: Samsung Electronics Co., Ltd., Suwon-si (KR)

(21) Appl. No.: 14/079,623

(22) Filed: Nov. 13, 2013

(30) Foreign Application Priority Data
Feb. 13, 2013 (KR) 10-2013-0015293

(51) Int. Cl. H01L 23/31

(52) U.S. Cl. CPC H01L 23/3157
USPC 257/620; 257/787

(57) ABSTRACT

Provided are semiconductor packages and methods of forming the same. A sidewall of a semiconductor chip in the package is exposed. Thus, the package has a size substantially equal to that of a wafer level package. Additionally, the semiconductor chip is mounted on a package substrate and a mold layer fills a space between the package substrate and the semiconductor chip. Thus, when the package is mounted on a mother board, a generated stress may be relieved by the package substrate and the mold layer. Thus, a board level reliability may be improved.

### CROSS-REFERENCE TO RELATED APPLICATIONS

This U.S. non-provisional patent application claims priority under 35 U.S.C. §119 to Korean Patent Application No. 10-2013-0015293, filed on Feb. 13, 2013, the entirety of which is incorporated by reference herein.

### BACKGROUND

The disclosed subject matter relates to semiconductor packages and methods of forming the same.

Semiconductor packages have been variously developed for their small size, lightness and low manufacture costs. Various kinds of the semiconductor packages have been used for various applications. A ball grid array (BGA) package may be formed by a mounting process, a molding process, and a solder ball bonding process. That is, a semiconductor chip may be mounted on a printed circuit board and then the molding process may be performed on the mounted semiconductor chip. Subsequently, the solder balls may be bonded to a bottom surface of the printed circuit board. The molding process should be required for the formation of the BGA package. Additionally, the BGA package uses the printed circuit board. Thus, size reduction of the BGA package may be limited. A wafer level package (WLP) package has been suggested in order to resolve the problems of the BGA package. In the WLP package, a redistribution pattern may be formed on a bottom surface of a semiconductor chip and then solder balls may be directly bonded to the redistribution pattern without a molding process. That is, the WLP package may not need the molding process and the printed circuit board. Thus, the WLP package may have a simple structure and a size of the WLP package may be reduced.

### SUMMARY

Embodiments of the disclosed subject matter may provide semiconductor packages having improved reliability and a reduced size.

Embodiments of the disclosed subject matter may also provide methods of forming a semiconductor package having improved reliability and a reduced size.

In one aspect, a semiconductor package may include: a package substrate; a semiconductor chip mounted on the package substrate using a flip chip bonding technique; and a mold layer filling a space between the package substrate and the semiconductor chip. A sidewall of the semiconductor chip may not be covered by the mold layer but may be exposed.

In some embodiments, the sidewall of the semiconductor chip may be substantially coplanar with sidewalls of the mold layer and the package substrate.

In some embodiments, the semiconductor chip may include a chip part and a scribe lane part disposed at an edge of the chip part; and a sidewall of the scribe lane part may be exposed.

In some embodiments, a step difference may occur between a bottom surface of the scribe lane part facing the package substrate and a bottom surface of the chip part facing the package substrate. In this case, a distance from the package substrate to the bottom surface of the scribe lane part may be greater than a distance from the package substrate to the bottom surface of the chip part. The sidewall of the scribe lane part may have a surface roughness different from that of a sidewall of the chip part.

In some embodiments, a bottom surface of the scribe lane part may be substantially coplanar with a bottom surface of the chip part.

In some embodiments, the semiconductor package may further include: an upper mold layer covering a top surface of the semiconductor chip and exposing the sidewall of the semiconductor chip.

In another aspect, a method of forming a semiconductor package may include: cutting a wafer including chip parts and a scribe lane part between the chip parts to form individual semiconductor chips, each of the individual semiconductor chips including each of the chip parts and a scribe lane part disposed at an edge of each of the chip parts; mounting the individual semiconductor chips on a package substrate by using a flip chip bonding technique; filling spaces between the package substrate and the individual semiconductor chips with a mold layer; and successively cutting the mold layer and the package substrate.

In some embodiments, cutting the wafer to form the individual semiconductor chips may include removing a portion of the scribe lane part of the wafer to form a groove exposing a sidewall of the chip part, the groove having a first width; and sawing the scribe lane part of a bottom of the groove by a blade having a second width less than the first width to form the individual semiconductor chips.

In some embodiments, the groove may be formed using a laser.

In some embodiments, the mold layer may be formed to extend onto top surfaces of the semiconductor chips.

### BRIEF DESCRIPTION OF THE DRAWINGS

The disclosed subject matter will become more apparent in view of the attached drawings and accompanying detailed description.

FIG. 1 is a cross-sectional view illustrating a semiconductor package according to some embodiments of the disclosed subject matter;

FIGS. 2 to 6 are cross-sectional views illustrating a method of forming a semiconductor device of FIG. 1;

FIG. 7 is a cross-sectional view illustrating a semiconductor package according to other embodiments of the disclosed subject matter;

FIG. 8 is a cross-sectional view illustrating a semiconductor package according to still other embodiments of the disclosed subject matter;

FIG. 9 illustrates an example of package modules including semiconductor packages according to embodiments of the disclosed subject matter;

FIG. 10 is a schematic block diagram illustrating an example of electronic systems including semiconductor packages according to embodiments of the disclosed subject matter; and

FIG. 11 is a schematic block diagram illustrating an example of memory systems including semiconductor packages according to some embodiments of the disclosed subject matter.

FIG. 12 is a flowchart illustrating an example of a technique according to embodiments of the disclosed subject matter.

### DETAILED DESCRIPTION OF THE EMBODIMENTS

The disclosed subject matter will now be described more fully and with reference to the accompanying drawings, in which exemplary embodiments of the disclosed subject matter are shown. The advantages and features of the disclosed subject matter and methods of achieving the matter will be apparent from the following exemplary embodiments that will be described in more detail with reference to the accompanying drawings. It should be noted, however, that the disclosed subject matter is not limited to the following exemplary embodiments, and may be implemented in various forms. Accordingly, the exemplary embodiments are provided only to illustrate the disclosed subject matter and let those skilled in the art know the category of the disclosed subject matter. In the drawings, embodiments of the disclosed subject matter are not limited to the specific examples provided herein and are exaggerated for clarity.

The terminology used herein is for the purpose of describing particular embodiments only and is not intended to limit the disclosed subject matter. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the disclosed subject matter. Accordingly, shapes of the exemplary views may be modified according to manufacturing techniques and/or allowable errors. Therefore, the embodiments of the disclosed subject matter are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the disclosed subject matter.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present disclosed subject matter. Exemplary embodiments of aspects of the present disclosed subject matter explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

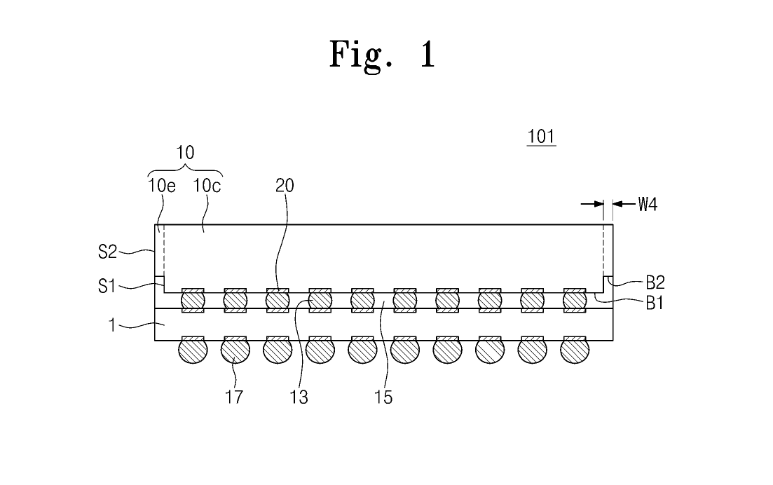

FIG. 1 is a cross-sectional view illustrating a semiconductor package according to some embodiments of the disclosed subject matter.

Referring to FIG. 1, a semiconductor package 101 according to the present embodiment includes a semiconductor chip 10 mounted on a package substrate 1 using a flip chip bonding technique. Internal solder balls 13 may be disposed between the semiconductor chip 10 and the package substrate 1. The semiconductor chip 10 may include bonding pads 20. A surface of the semiconductor chip 10 adjacent to the bonding pads 20 may be disposed to be adjacent to the package substrate 1, and the internal solder balls 13 may be in contact with the bonding pads 20, respectively. External solder balls 17 may be bonded to a bottom surface of the package substrate 1.

A mold layer 15 may fill a space between the semiconductor chip 10 and the package substrate 1. The semiconductor chip 10 may include a chip part 10c and a scribe lane part 10e surrounding an edge of the chip part 10c. A circuit region may be formed on the chip part 10c. A misalignment key and/or a test circuit pattern may be formed on the scribe lane part 10e. For example, a width W4 of the scribe lane part 10e may be equal to or less than about 40 μm.

A sidewall S2 of the scribe lane part 10e may not covered by the mold layer 15 but may be exposed. The sidewall S2 of the scribe lane part 10e, a sidewall of the mold layer 15, and a sidewall of the package substrate 1 may be aligned with each other and may be substantially coplanar with each other. A step difference may occur between a bottom surface B2 of the scribe lane part 10e and a bottom surface B1 of the chip part 10c. A distance from a top surface of the package substrate 1 to the bottom surface B2 of the scribe lane part 10e may be greater than a distance from the top surface of the package substrate 1 to the bottom surface B1 of the chip part 10c.

A sidewall S1 of the chip part 10c may be covered by the mold layer 15. The sidewall S1 of the chip part 10c may have a surface roughness different from that of the sidewall S2 of the scribe lane part 10e.

As described above, the sidewall S2 of the semiconductor chip 10 may be exposed. Thus, the semiconductor package 101 having the aforementioned structure may have a size substantially equal to a size of a wafer level package. As a result, the size of the semiconductor package 101 may be reduced. Additionally, an amount of stress generated when the semiconductor package 101 is mounted on a mother board may be relieved through the package substrate 1, the mold layer 15, and the external solder balls 17. Thus, a board level reliability may be improved.

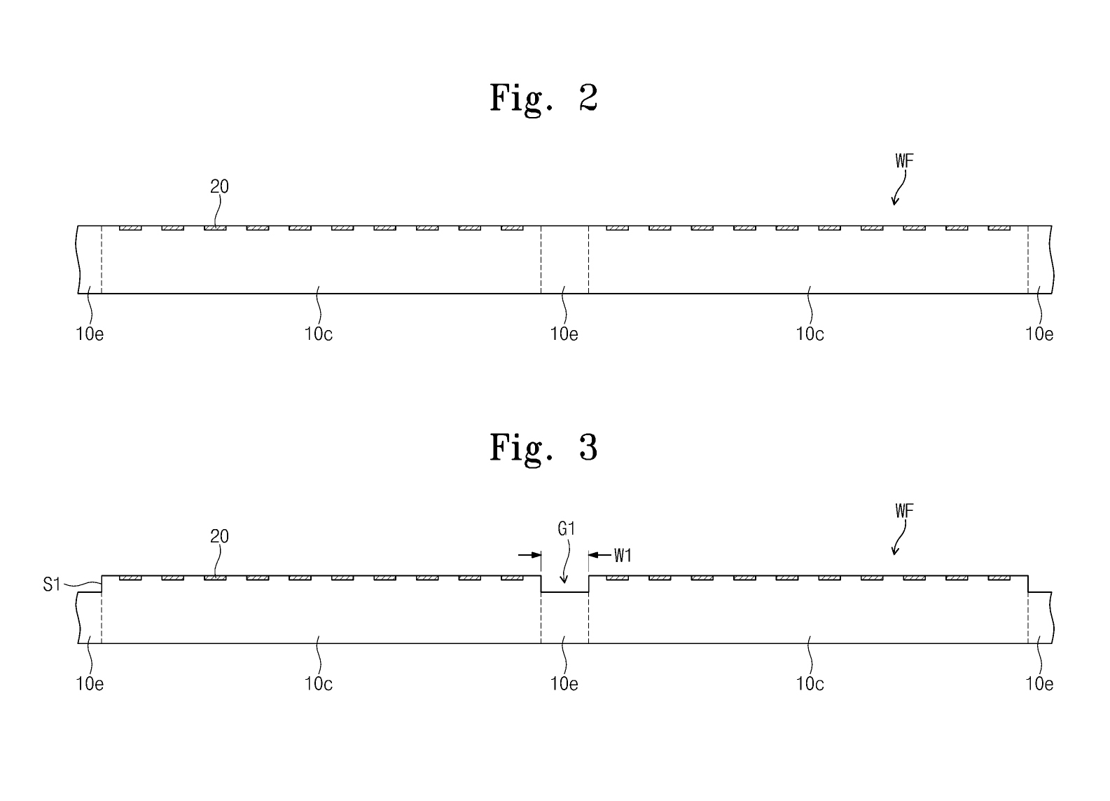

FIGS. 2 to 6 are cross-sectional views illustrating a method of forming a semiconductor device of FIG. 1 according to some embodiments.

Referring to FIG. 2, a wafer WF may be formed to have a plurality of chip parts 10c and scribe lane parts 10e disposed between the chip parts 10c. Even though not shown in the drawings, various circuits including transistors and interconnections may be formed on the chip parts 10c. Bonding pads 20 may be disposed on the circuits. Misalignment marks (or misalignment keys) and/or test circuit patterns may be formed on the scribe lane parts 10e.

Referring to FIG. 3, a first sawing process may be performed to remove portions of the scribe lane parts 10e between the chip parts 10c, thereby forming a groove G1 having a first width W1. The first width W1 may substantially correspond to a width of the scribe lane part 10e. A depth of the groove G1 may be within a range of about 10 μm to about 20 μm. In one example, the first sawing process may be performed using a laser. For example, the first width W1 may be about 100 μm.

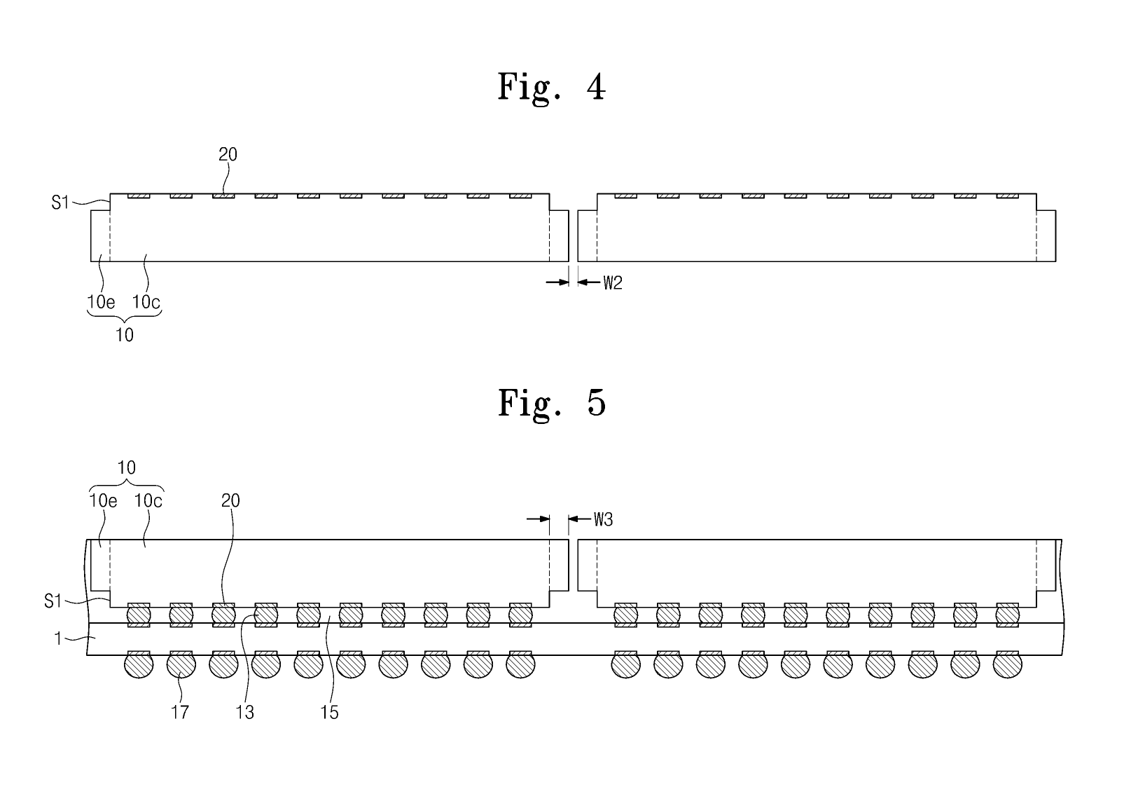

Referring to FIG. 4, a second sawing process may be performed to cut the scribe lane parts 10e of a bottom of the groove G1. Thus, the wafer WF is divided into individual semiconductor chips 10. At this time, the second sawing process may be performed using a diamond cutter or blade having a width less than the first width W1. Thus, a width of the removed scribe lane part 10e may correspond to a second width W2. For example, the second width W2 may be about 20 μm.

Referring to FIG. 5, each of the semiconductor chips 10 may be overturned or inverted, and then may be mounted on a package substrate 1 using a flip chip bonding technique. At this time, the bonding pads 20 of each semiconductor chip 10 may be adjacent to the package substrate 1 and internal solder balls 13 may be disposed between the package substrate 1 and the bonding pads 20 of each semiconductor chip 10. The mounted semiconductor chip 10 includes a chip part 10c and a scribe lane part 10e. A third width W3 of the scribe lane part 10e of the mounted semiconductor chip 10 may correspond to half of a value obtained by subtracting the second width W2 from the first width W1 (i.e., W3=(W1−W2)/2). A molding process may be performed to form a mold layer 15 filling spaces between the package substrate 1 and the semiconductor chips 10. At this time, the mold layer 15 may also fill a space between the semiconductor chips 10 adjacent to each other. Additionally, external solder balls 17 are bonded to a bottom surface of the package substrate 1.

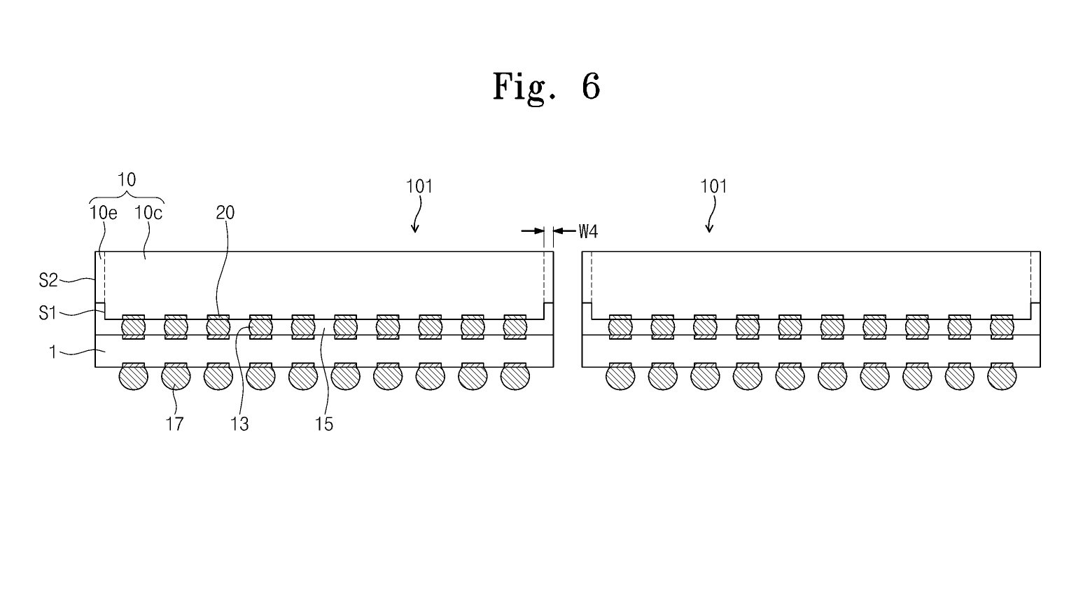

Referring to FIG. 6, a singulation process may be performed to cut the mold layer 15 and the package substrate 1. Thus, individual semiconductor packages 101 may be separated from each other. At this time, a sidewall S2 of the scribe lane part 10e of the individual semiconductor package 101 is exposed. Additionally, a portion of the scribe lane part 10e of the individual semiconductor package 101 may also be removed at this time. Thus, the scribe lane part 10e of the individual semiconductor package 101 may have a fourth width W4. The fourth width W4 may be substantially equal to or less than the third width W3.

As a result, the semiconductor package 101 may be completed.

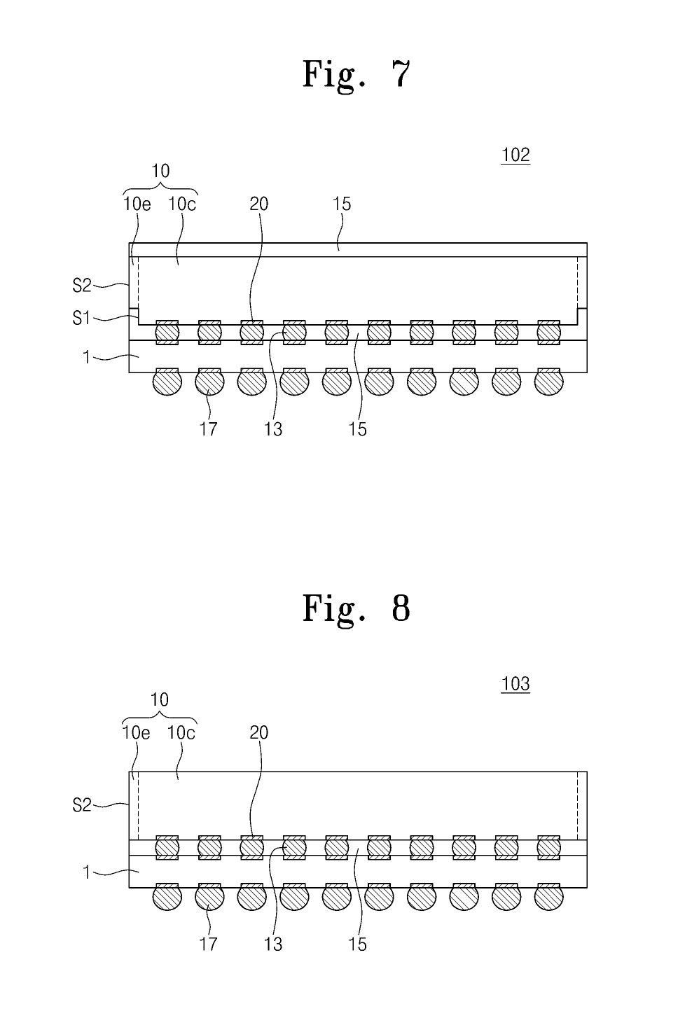

FIG. 7 is a cross-sectional view illustrating a semiconductor package according to other embodiments of the disclosed subject matter.

Referring to FIG. 7, a mold layer 15 may further cover a top surface of the semiconductor chip 10 in a semiconductor package 102 according to the present embodiment. Other elements of the semiconductor package 102 may be the same as corresponding elements of the semiconductor package 101 illustrated in FIG. 1. When the molding process of FIG. 5 is performed, the mold layer 15 may further cover, at least partially, one or more top surfaces of the semiconductor chips 10. Thus, the semiconductor package 102 of the present embodiment may be formed. Other formation processes of the semiconductor package 102 may be the same as or similar to corresponding processes described with reference to FIGS. 2 to 6.

FIG. 8 is a cross-sectional view illustrating a semiconductor package according to still other embodiments of the disclosed subject matter.

Referring to FIG. 8, a bottom surface of a scribe lane part 10e may be substantially coplanar with a bottom surface of a chip part 10c without a step difference in a semiconductor package 103 according to the present embodiment. Thus, an entire sidewall of the chip part 10c may be in contact with the scribe lane part 10e. Other elements of the semiconductor package 103 may be the same as corresponding elements of the semiconductor package 101 illustrated in FIG. 1.

Semiconductor chips 10 may be cut by one sawing process in order to form the semiconductor package 103 according to the present embodiment. At this time, the scribe lane part 10e may have the third width W3. Subsequently, the cut semiconductor chip 10 may be mounted on a package substrate 1 and then a molding process may be performed. Next, a singulation process may be performed to form the semiconductor package 103. Other formation processes of the semiconductor package 103 may be the same as or similar to corresponding processes described with reference to FIGS. 2 to 6.

The semiconductor package techniques described above may be applied to various kinds of semiconductor devices and package modules thereof.

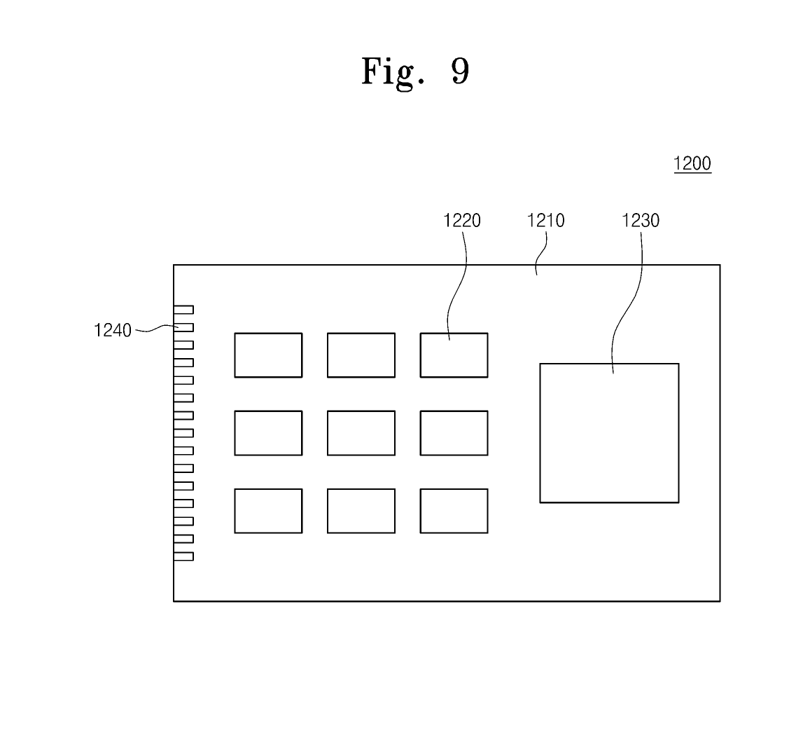

FIG. 9 illustrates an example of package modules including semiconductor packages according to embodiments of the disclosed subject matter. Referring to FIG. 9, a package module 1200 may include a semiconductor integrated circuit device 1220 and a semiconductor integrated circuit device 1230 packaged using a quad flat package (QFP) technique. The devices 1220 and 1230 may be mounted on a board 1210. The devices 1220 and 1230 applied with the aforementioned semiconductor package techniques of the disclosed subject matter may be installed to form the package module 1200. The package module 1200 may be connected to an external electronic device through external connection terminals 1240 provided on a side of the board 1210.

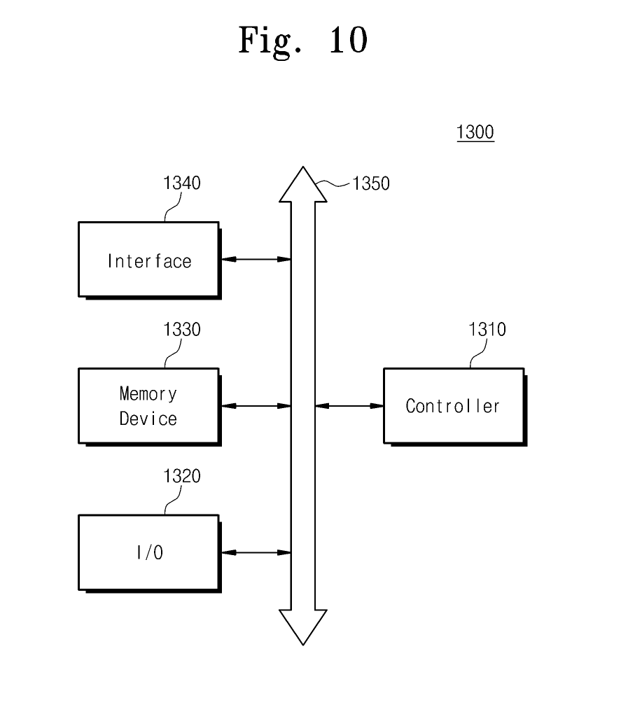

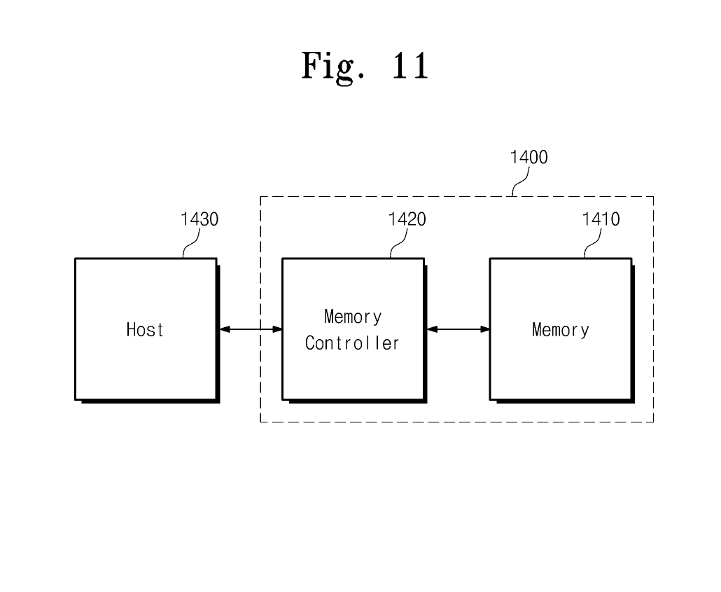

The aforementioned semiconductor package techniques may be applied to an electronic device. FIG. 10 is a schematic block diagram illustrating an example of electronic systems including semiconductor packages according to embodiments of the disclosed subject matter. Referring to FIG. 10, an electronic system 1300 may include a controller 1310, an input/output (I/O) unit 1320, and a memory device 1330. The controller 1310, the I/O unit 1320, and the memory device 1330 may communicate with each other through a data bus 1350. The data bus 1350 may correspond to a path through which electrical signals are transmitted. For example, the controller 1310 may include at least one of a microprocessor, a digital signal processor, a microcontroller, or other logic devices having a similar function to any one of the microprocessor, the digital signal processor and the microcontroller. The controller 1310 and the memory device 1330 may include at least one of the semiconductor packages according to the aforementioned embodiments of the disclosed subject matter. The I/O unit 1320 may include a keypad, a keyboard and/or a display unit. The memory device 1330 stores data. The memory device 1330 may store data and/or commands executed by the controller 1310. The memory device 1330 may include a volatile memory device and/or a non-volatile memory device. In some embodiments, the memory device 1330 may include a flash memory device. For example, the flash memory device applied with the semiconductor package technique according to the disclosed subject matter may be installed in an information processing system such as a mobile device or a desktop computer. The flash memory device may be realized as solid state disks (SSD). In this case, the electronic system 1300 may stably store massive data in the memory device 1330. The electronic system 1300 may further include an interface unit 1340 that transmits electrical data to a communication network or receives electrical data from a communication network. The interface unit 1340 may operate by wireless or cable. For example, the interface unit 1340 may include an antenna for wireless communication or a transceiver for cable communication. Although not shown in the drawings, the electronic system 1300 may further include an application chipset and/or a camera image processor (CIS).

The electronic system 1300 may be realized as a mobile system, a personal computer, an industrial computer, or a multi-functional logic system. For example, the mobile system may be one of a personal digital assistant (PDA), a portable computer, a web tablet, a wireless phone, a mobile phone, a laptop computer, a digital music player, a memory card, or an information transmitting/receiving system. If the electronic system 1300 is an apparatus capable of performing a wireless communication, the electronic device 1300 may be used in a communication interface protocol such as a third generation communication system (e.g., CDMA, GSM, NADC, E-TDMA, WCDMA, CDMA2000).

The semiconductor package according to the aforementioned embodiments may be provided in a memory system. FIG. 11 is a schematic block diagram illustrating an example of memory systems including semiconductor packages according to embodiments of the disclosed subject matter. Referring to FIG. 11, a memory system 1400 may include a non-volatile memory device 1410 and a memory controller 1420. The non-volatile memory device 1410 and the memory controller 1420 may store data or may read stored data. The non-volatile memory device 1420 may include at least one of non-volatile memory devices applied with the semiconductor package techniques according to the aforementioned embodiments of the disclosed subject matter. The memory controller 1420 may read data from/store data into the non-volatile memory device 1410 in response to read/write request of a host 1430.

The semiconductor package according to embodiments of the disclosed subject matter may have the size substantially equal to that of the wafer level package. Additionally, the semiconductor chip of the semiconductor package is mounted on the package substrate, and the mold layer fills the space between the semiconductor chip and the package substrate. Thus, the stress generated when the semiconductor package is mounted on the mother board may be relieved by the package substrate and the mold layer. Thus, the board level reliability may be improved.

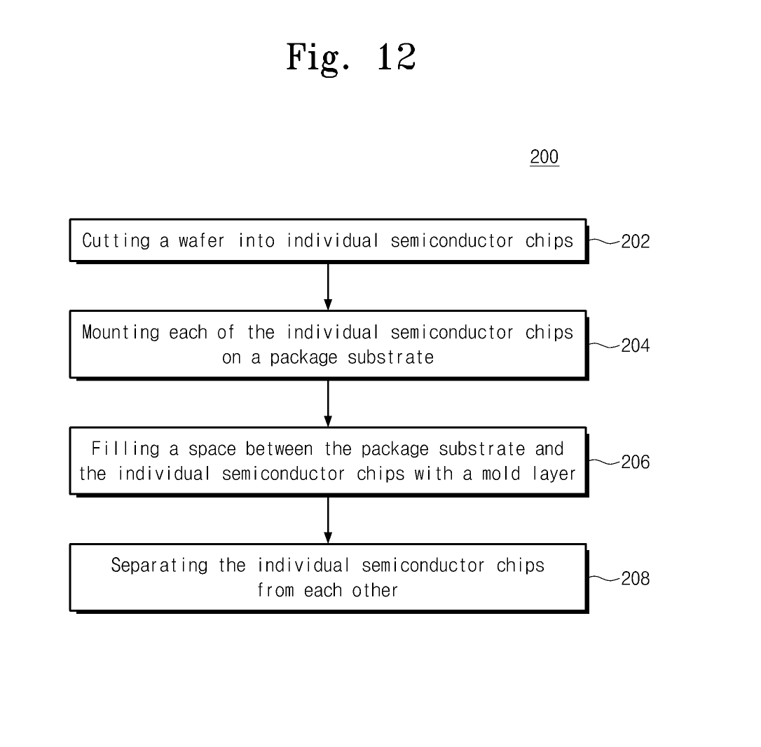

FIG. 12 is a flow chart of an example embodiment of a technique 200 in accordance with the disclosed subject matter. In various embodiments, the technique 200 may be used or produced by the systems such as those of FIG. 1, 7, 8, 9, 10, or 11. Furthermore, portions of technique 200 may be used to produce the systems such as that of FIG. 2, 3, 4, 5, or 6. Although, it is understood that the above are merely a few illustrative examples to which the disclosed subject matter is not limited. It is understood that the disclosed subject matter is not limited to the ordering of or number of actions illustrated by technique 200.

Block 202 illustrates that, in one embodiment, a wafer may be cut into individual semiconductor chips, as described above. In one embodiment, the wafer may include a plurality of chip parts and a plurality of scribe lane parts, as described above. In such an embodiment, cutting the wafer may include cutting between the chip parts to form individual semiconductor chips. In various embodiments, each of the individual semiconductor chips may include one chip part and a scribe lane part disposed at least one edge of the one chip part, as described above.

In some embodiments, cutting may include removing a portion of each of the scribe lane parts to form a groove on each scribe lane part, as described above. In such an embodiment, the groove may expose a sidewall of the chip part and include a first width, as described above. In various embodiments, removing may include removing a portion of each of the scribe lane parts of the wafer to form a groove by using a laser, as described above. In some embodiments, cutting may also include cutting a bottom of the groove with a cutting device having a second width less than the first width to form the individual semiconductor chips, as described above.

In another embodiment, cutting may include removing a portion of a combined scribe lane part to form two scribe lane parts, as described above. In such an embodiment, the combined scribe lane part may be included by the wafer, as described above. In such an embodiment, each scribe lane part may be included by respective individual semiconductor chip, as described above. In such an embodiment, the combined scribe lane part may include a width less than or equal to 100 micrometers (μm), as described above. Further, in various embodiments, the portion of the combined scribe lane part that is removed may include a width substantially equal to 20 μm, as described above.

In various embodiments, one or more of the action(s) illustrated by this Block may be performed by the apparatuses or systems of FIG. 2, 3, or 4, as described above.

Block 204 illustrates that, in one embodiment, each of the individual semiconductor chips may be mounted on a package substrate, as described above. In various embodiments, the semiconductor chip may be mounted with the package substrate by a flip chip bonding technique, as described above. In various embodiments, one or more of the action(s) illustrated by this Block may be performed by the apparatuses or systems of FIG. 5 or 6, as described above.

Block 206 illustrates that, in one embodiment, a space between the package substrate and the individual semiconductor chips may be filled, at least partially, with a mold layer, as described above. In various embodiments, the mold layer may be disposed to extend onto at least a portion of a top surface of each individual semiconductor chip, as described above. In various embodiments, one or more of the action(s) illustrated by this Block may be performed by the apparatuses or systems of FIG. 5 or 6, as described above.

Block 208 illustrates that, in one embodiment, the individual semiconductor chips may be separated from each other by cutting a portion of the scribe lane part of each respective individual semiconductor chip, a portion of the mold layer, and a portion of the package substrate, as described above. In various embodiments, one or more of the action(s) illustrated by this Block may be performed by the apparatuses or systems of FIG. 5 or 6, as described above.

While the disclosed subject matter has been described with reference to example embodiments, it will be apparent to those skilled in the art that various changes and modifications may be made without departing from the spirit and scope of the disclosed subject matter. Therefore, it should be understood that the above embodiments are not limiting, but illustrative. Thus, the scope of the disclosed subject matter is to be determined by the broadest permissible interpretation of the following claims and their equivalents, and shall not be restricted or limited by the foregoing description.

1. A semiconductor package comprising:
a package substrate;
a semiconductor chip mounted with the package substrate; and
a mold layer filling, at least partially, a space between the package substrate and the semiconductor chip,
wherein a portion of a sidewall of the semiconductor chip is exposed and is not covered by the mold layer.

2. The semiconductor package of claim 1, wherein the sidewall of the semiconductor chip is substantially coplanar with a sidewall of the mold layer and a sidewall the package substrate.

3. The semiconductor package of claim 1, wherein the semiconductor chip includes a chip part and a scribe lane part that is disposed at an edge of the chip part; and
wherein the scribe lane part includes the portion of the sidewall of the semiconductor chip that is exposed.

4. The semiconductor package of claim 3, wherein a bottom surface of the scribe lane part that faces the package substrate is disposed a step difference from a bottom surface of the chip part that faces the package substrate.

5. The semiconductor package of claim 3, wherein a distance from the package substrate to a bottom surface of the scribe lane part is greater than a distance from the package substrate to a bottom surface of the chip part.

6. The semiconductor package of claim 3, wherein the scribe lane part that includes the portion of the sidewall of the semiconductor chip that is exposed includes a surface roughness different from that of a sidewall of the chip part.

7. The semiconductor package of claim 3, wherein a bottom surface of the scribe lane part is substantially coplanar with a bottom surface of the chip part.

8. The semiconductor package of claim 1, further comprising:
an upper mold layer disposed to cover a top surface of the semiconductor chip.

9-12. (canceled)

13. The semiconductor package of claim 1, wherein the semiconductor chip is mounted with the package substrate by a flip chip bonding technique.

14. An apparatus comprising:
a board configured to be electrically coupled with an external electronic device; and
a plurality of semiconductor devices each configured to be mounted with the board,
wherein the plurality of semiconductor devices includes a semiconductor package;
the semiconductor package comprising:
a package substrate;
a semiconductor chip coupled with the package substrate; and
a mold layer disposed between the package substrate and the semiconductor chip and disposed to only partially cover a sidewall of the semiconductor chip.

15. The apparatus of claim 14, wherein the semiconductor chip includes a chip part having a first height, and a scribe lane part having a second height that is less than the first height;
wherein a difference in height between the chip part and the scribe lane part forms a groove; and
wherein mold layer is disposed to, at least partially, fill the groove.

16. The apparatus of claim 14, wherein the semiconductor package further includes an upper mold layer disposed to cover, at least partially, a top surface of the semiconductor chip.

17. The apparatus of claim 14, wherein the semiconductor chip includes a chip part having an outer sidewall having a first surface roughness, and a scribe lane part having an external sidewall having a second surface roughness that is different from the first surface roughness.

18. The apparatus of claim 14, wherein the semiconductor chip includes a scribe lane part including, at least a portion of, a misalignment key.

19. The apparatus of claim 14, wherein the semiconductor chip includes a scribe lane part including:
a width less than or equal to 40 micrometers (μm), and
a groove having a groove depth of between 10 μm to 20 μm, inclusive.

20. (canceled)
